(19) United States
(12) Patent Application Publication
(10) Pub. No.: US 2026/0079538 A1
(43) Pub. Date: Mar. 19, 2026

(54) System for Securing a Mobile Computing Device to a Bar, Pipe or Spar

(71) Applicant: WhitServe LLC, Stamford, CT (US)

(72) Inventors: Declan W. Whitmyer, Stamford, CT (US); Salvador Sanchez, Acapulco de Juárez (MX)

(21) Appl. No.: 19/333,685

(22) Filed: Sep. 19, 2025

Related U.S. Application Data
(60) Provisional application No. 63/696,657, filed on Sep. 19, 2024.

(51) Int. Cl. G06F 1/16; H05K 5/02

(52) U.S. Cl. CPC G06F 1/1656; H05K 5/0204

(57) ABSTRACT

A mounting strap system for removably securing a mobile computing device to a mast, spar, rail, or other tubular object is disclosed. The system includes a strap formed of double-sided hook-and-loop fastening material that can be wrapped around the tubular object and secured to itself. A finger loop at one end of the strap allows the strap to be tightened under tension prior to fastening. The strap further defines a through-hole for receiving a fastener, wedge, pins, or a backing plate to reduce rotation. The backing plate may support a releasable device mount adapted to interface with various commercially available mounting systems. In certain embodiments, a spacer or stand-off positions the mobile computing device away from the tubular surface to create a gap for cables or control lines. The system provides a secure, versatile, and easily removable means of attaching a mobile computing device to tubular structures of varied cross-section.

### TECHNICAL FIELD

The present invention relates to a mounting strap system configured for removably securing a mobile computing device to a tubular object, such as the mast or spar of a sailboat, or alternatively a rail or superstructure of a motorboat without tools.

### BACKGROUND

Mobile computing devices, and in particular, smartphones are increasingly being used as instruments for sport vehicles such as cars, boats, planes, bikes and the like. For accurate use as an instrument and easy viewing by the sport participant, the mobile computing device must be securely mounted. Most sport vehicles require mounting to a curved surface such as a bar, pipe or spar.

Consequently, most mounting systems available on the market require tools for installation and/or are only designed to fit a single size and/or shape bar, pipe, spar or the like. But sport participants often have multiple different vehicles to which they desire to mount their single smartphone. For example, different sailboats have different shapes and diameter spars, different motorcycles have different diameter handlebars. What is desired, therefore, is a system for securely mounting a mobile computing device to a variety of sporting vehicles having bars, pipes or spars of varying sizes. It is also desired that the mounting system can be removed and repeatedly used on different sport vehicles having different mounting conditions.

### SUMMARY

Accordingly, the invention provides a device for securely mounting and remounting a mobile computing device (MCD) such as a smartphone to a sport vehicle which has bars, tubes, spars, or other curved surfaces of varying shapes and sizes.

The present invention relates to a mounting strap system for removably securing a mobile computing device to a mast, spar, rail, or other generally tubular object. The system provides a simple, lightweight, and reversible solution for attaching a device without permanent modification to the support structure.

In one aspect, the invention includes a strap formed of double-sided hook-and-loop fastening material that can be wrapped around a tubular object and secured to itself. A finger loop at one end of the strap allows the user to apply significant tension by pulling the loop and the strap end in opposite directions prior to engaging the fastening surfaces, enabling a tight and secure fit even on irregularly shaped cross-sections.

In another aspect, the strap defines a through-hole that may receive a fastener, a wedge, or one or more pins configured to engage complementary structures on the tubular member, thereby reducing the likelihood of rotation. The through-hole may also accommodate a base or backing plate that distributes load and resists sliding. The backing plate may support a mount adapted to releasably secure a mobile computing device, which may be implemented using a variety of commercially available mounting systems.

In another aspect, the system may include a spacer or stand-off configured to move the mounted device away from the surface of the mast or tubular object. This creates a gap that permits sail control lines, electrical cables, or other rigging to pass between the device and the support structure. By offsetting the device, both rear-facing and forward-facing cameras benefit from less obstructed fields of view.

The combination of a tensioning strap, fastening surfaces, through-hole, backing plate, mount, optional wedge or pins, and optional spacer or stand-off provides a versatile and secure mounting system. The invention may be applied to a wide variety of mast or tubular cross-sections and reduces the possibility of rotation while maintaining removability and ease of use.

### BRIEF DESCRIPTION OF THE DRAWINGS

FIG. 1 is a perspective view of a mounting strap wrapped around a mast or tubular object, showing a finger loop and hook-and-loop fastening surfaces.

FIG. 2 is a perspective view of the mounting strap including a through-hole for receiving a fastener, wedge, or pins to resist rotation.

FIG. 3 is a perspective view of the mounting strap with a backing plate extending through the through-hole and supporting a mobile computing device mount.

FIG. 4 is a perspective view of the mounting strap system with an optional spacer and U-shaped stand-off providing a gap between the mast and a mounted mobile computing device.

FIG. 5 is a schematic view of alternative mast or tubular cross-sectional shapes to which the mounting strap system may be applied.

### DETAILED DESCRIPTION

The present teachings are described more fully hereinafter with reference to the accompanying drawings, in which the present embodiments are shown. The following description is presented for illustrative purposes only, and the present teachings should not be limited to these embodiments.

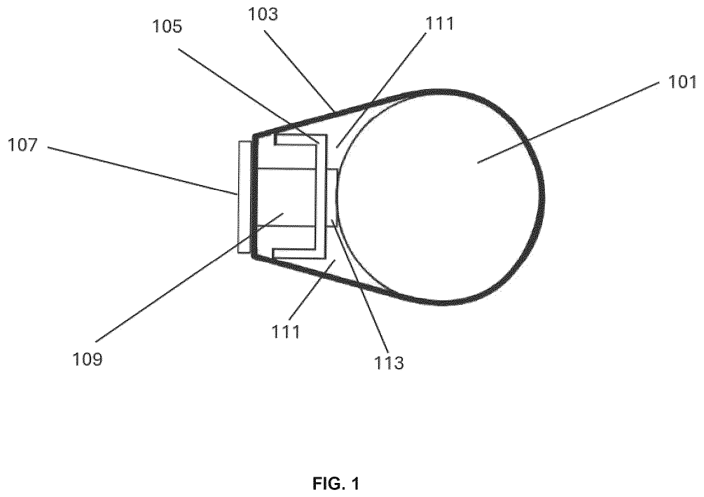

FIG. 1 illustrates a mounting strap system configured to removably secure a mobile computing device to a mast or other tubular member (101). A strap (103) formed of double-sided hook-and-loop material is wrapped around the mast (101) and secured to itself by engagement of a hook fastener (119) and a loop fastener (120). A finger loop (117) is provided at one end of the strap (103). During use, the free end of the strap (103) is threaded through the finger loop (117) and tension is applied by pulling the loop (117) and strap end in opposite directions before fastening. This tightening method ensures that the strap (103) is securely attached to the mast (101), even when the mast has an irregular cross-section. Stitching (115) reinforces the strap (103) and maintains the integrity of the finger loop (117).

As shown in FIG. 1, the system includes a strap (103), preferably constructed of a double-sided strip of hook-and-loop fastening material. The strap (103) is configured to be wrapped around the mast (101) or other generally tubular member and secured to itself by the engagement of a hook fastener (119) with a loop fastener (120). This allows for simple, rapid, and reversible attachment without the need for separate tools or permanent modifications to the mast (101).

To assist in securing the strap (103) tightly around the mast (101), the strap includes a finger loop (117) formed at one end. In use, a free end of the strap (103) is threaded through the finger loop (117), and the user then pulls the loop (117) and the free end of the strap (103) in opposite directions to apply tension before engaging the hook (119) and loop (120) fastening surfaces. This tightening mechanism allows the strap (103) to be drawn tightly against the mast (101), even if the mast or tubular member is irregular in cross-section, thereby reducing the risk of rotation of the strap during use.

The strap (103) may further include stitching (115) at selected locations to reinforce the strap and secure the finger loop (117) in place.

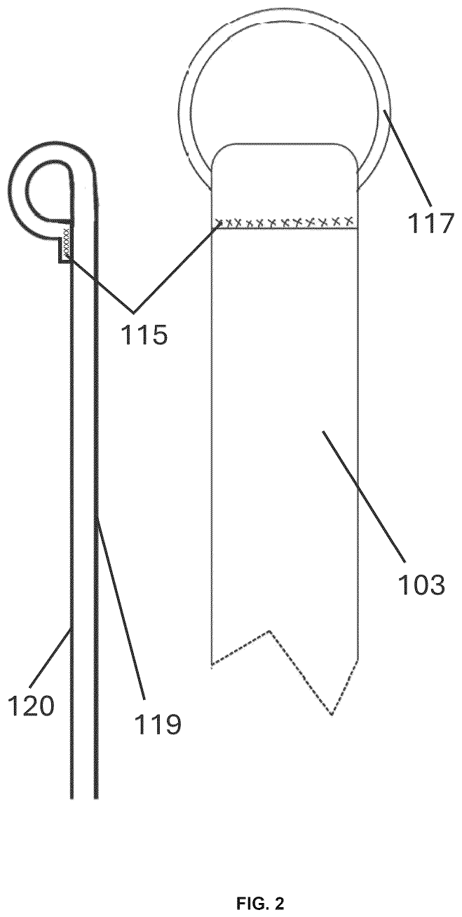

FIG. 2 shows the strap (103) with a through-hole (121). The through-hole (121) allows additional components to be employed for stability. For example, a fastener (123), such as a screw or rivet, may extend through the hole (121) into the mast (101). Alternatively, the through-hole (121) may accommodate a fin or wedge (125) or one or more pins (127). These elements engage with a slot or recess on the mast (101) to further resist rotation of the strap (103).

In one embodiment, as illustrated in FIG. 2, the strap (103) defines a through-hole (121). The through-hole (121) provides several functional benefits. First, it allows the optional placement of a fin or wedge (125), or one or more pins (127), which extend from the strap (103) to engage with a corresponding slot, groove, or aperture on the mast (101). Such engagement further reduces the possibility of rotational movement of the strap relative to the mast. In another embodiment, the through-hole (121) allows for the insertion of a mechanical fastener (123), such as a screw, bolt, or rivet, to provide supplemental fixation of the strap (103) to the mast (101).

In another embodiment, the through-hole (121) accommodates a base or backing plate (113). The backing plate (113) provides a semi-rigid surface to support the strap (103) and distribute loads applied by an attached mobile computing device. The backing plate (113) may further incorporate a non-skid surface to resist sliding relative to the mast (101), thereby reducing the possibility of strap rotation. The backing plate (113) may extend through the through-hole (121) to connect to an MCD mount (107), which is adapted to releasably secure a mobile computing device. The mount (107) may be configured according to a variety of commercially available systems, such as Quad Lock®, Peak Design®, SP Connect®, Rokform®, or equivalent designs, thereby allowing the invention to be practiced with many different mobile devices.

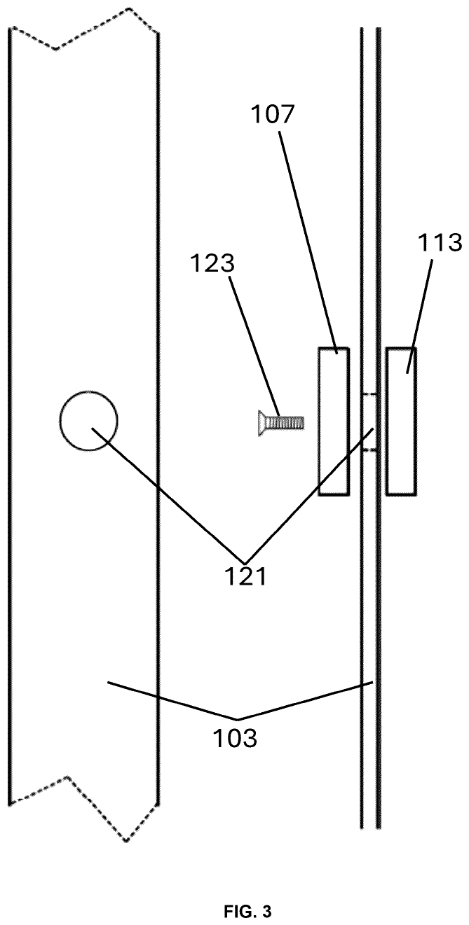

FIG. 3 illustrates an embodiment including a base or backing plate (113). The backing plate (113) passes through the strap (103) via the through-hole (121). The backing plate (113) provides a rigid or semi-rigid surface that distributes load across the mast (101) and resists sliding. The backing plate (113) supports an MCD mount (107), which may be any suitable releasable mounting system, including Quad Lock®, Peak Design®, SP Connect®, or Rokform®. The mount (107) secures a mobile computing device in place and is stabilized by the backing plate (113).

As illustrated in FIG. 3, the system may further include an optional spacer (109) interposed between the MCD mount (107) and the mast (101). In certain embodiments, the spacer (109) is combined with a U-shaped stand-off (105). The spacer (109) and stand-off (105) serve to move the plane of the mounted mobile computing device away from the front surface of the mast (101). This arrangement creates a gap (111) between the mast (101) and the mobile computing device, through which cables, sail control lines, or other rigging may be routed without obstructing the view of the display or interfering with a device camera.

By offsetting the device away from the mast (101), the invention improves the field of view of both rear-facing and forward-facing cameras of the mobile computing device. A rear-facing camera is provided with a wider angle of view that extends around the mast (101), while a forward-facing camera benefits from an unobstructed view due to passage of lines or cables behind the device.

In certain embodiments, the backing plate (113) and/or MCD mount (107) may include alignment features such as pins (127) or recesses designed to engage complementary structures on the mobile computing device or its protective case. Such features ensure consistent positioning and reduce unintended rotation of the mounted device relative to the mast (101).

The combination of the strap (103), finger loop (117), hook (119) and loop (120) fastening surfaces, through-hole (121), backing plate (113), mount (107), optional spacer (109), stand-off (105), wedge (125), and pins (127) provide a robust, versatile, and easily removable system for mounting a mobile computing device to a mast (101) or other tubular structure. The modularity of the system permits different embodiments to be selected depending on installation requirements, thereby allowing secure attachment while minimizing the potential for rotation or interference with sailing lines, cables, or other equipment.

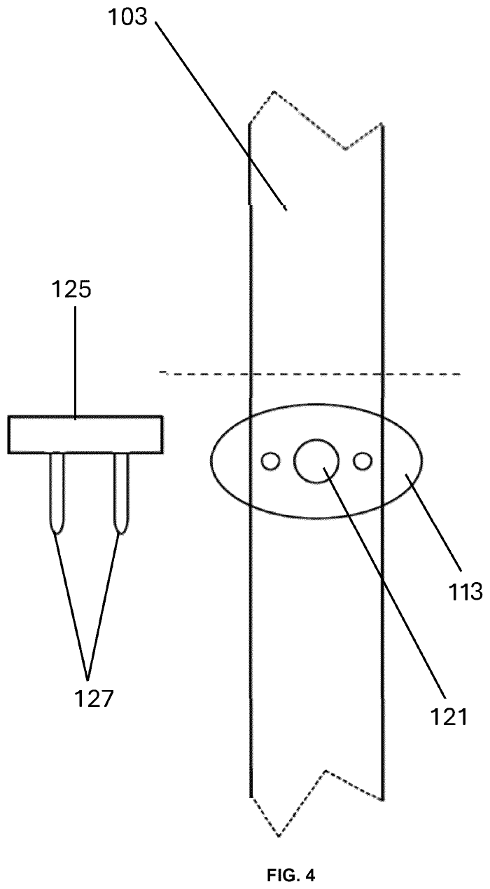

FIG. 4 shows an embodiment in which an optional spacer (109) and an optional U-shaped stand-off (105) are provided between the MCD mount (107) and the mast (101). The spacer (109) and stand-off (105) move the mounted mobile computing device away from the mast (101), creating a gap (111). The gap (111) allows control lines, electrical cables, or other rigging to pass without obstructing the device's display or interfering with front-or rear-facing cameras. The offset improves the device's field of view around the mast (101) and minimizes interference from ropes or wires.

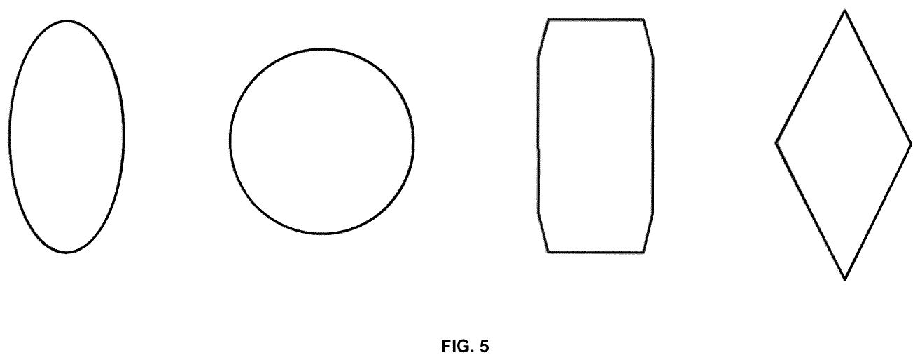

FIG. 5 illustrates alternative mast or tubular shapes (101) to which the mounting strap system may be applied. The system is not limited to circular cross-sections, and may be used with oval, polygonal, or irregularly shaped tubular members. The ability to tighten the strap (103) using the finger loop (117) and to secure it with the hook (119) and loop (120) fastening system enables the strap to conform securely to a variety of cross-sectional shapes. Optional components such as the wedge (125), pins (127), or backing plate (113) further reduce the risk of rotation on these non-circular cross-sections.

What is claimed is:

1. A system for mounting a mobile computing device to a curved surface, comprising:
a strap having first and second surfaces and wrapping over the curved surface;
hook fastening material on one of the first and second surfaces of the strap;
loop fastening material on the other of the first and second surfaces of the strap;
a channel formed in one end of the strap;
a finger loop passing through the channel;
a hole formed in the strap;
a base on one side of the strap adjacent to the hole;
a mount on the other side of the strap adjacent to the hole, the mount for removably connecting to the mobile computing device; and
a fastener for linking the base to the mount through the hole in the strap.

2. The system of claim 1 further comprising a belting material sandwiched between the hook and loop fastening materials at least in a region of the hole to provide extra strength to the strap.

3. The system of claim 1 further comprising a spacer to increase a distance between the base and the mount such that the mobile computing device is mounted in a position spaced further apart from the curved surface.

4. The system of claim 1 further comprising a U-shaped plate to move the strap away from the curved surface in a region of the hole to create passages for controls.

5. The system of claim 1 wherein the curved surface is the spar of a boat.

6. The system of claim 5 wherein the spar has a sail groove.

7. The system of claim 6 further comprising a tab extending from the base for interacting with the sail groove to reduce rotation of the strap around the spar.

8. The system of claim 7 wherein the tab comprises one or more rods.

9. The system of claim 7 wherein the tab comprises a wedge.

10. The system of claim 7 wherein the tab comprises a pliable plug.

11. The system of claim 1 wherein the base has a substantially planar back surface in contact with the curved surface.

12. The system of claim 1 wherein the base includes an adhesive back surface.

13. The system of claim 1 wherein the base has a portion of non-skid material on its back surface.

14. The system of claim 1 wherein the strap has at least one portion of non-skid material on at least one of its first and second surfaces to engage the curved surface.

15. The system of claim 1 wherein the channel is stitched.

16. The system of claim 1 wherein the hook and loop fastening materials are glued together.

17. The system of claim 1 wherein the finger loop is a single, spliced piece of line.

18. The system of claim 1 in which a free end of the strap is passed through the finger loop and the strap is securely mounted to the curved surface by pulling the free end and finger loop in opposite directions before fastening the hook and loop materials together.

19. The method of using a system for mounting a mobile computing device to a curved surface in which a free end of a strap having hook and loop materials is passed through a finger loop and the strap is securely mounted to a curved surface by pulling the free end and finger loop in opposite directions before fastening the hook and loop materials together.
